(19) United States
(12) Patent Application Publication
(10) Pub. No.: US 2014/0167158 A1
(43) Pub. Date: Jun. 19, 2014

(54) INTEGRATED DEVICE AND METHOD FOR FABRICATING THE INTEGRATED DEVICE

(71) Applicants: FOUNDER MICROELECTRONICS INTERNATIONAL CO., LTD., Shenzhen (CN); PEKING UNIVERSITY FOUNDER GROUP CO., LTD., Beijing (CN)

(72) Inventors: Guangran PAN, Beijing (CN); Yan WEN, Shenzhen (CN); Jincheng SHI, Shenzhen (CN); Zhenjie GAO, Shenzhen (CN)

(73) Assignees: FOUNDER MICROELECTRONICS INTERNATIONAL CO., LTD., Shenzhen (CN); PEKING UNIVERSITY FOUNDER GROUP CO., LTD., Beijing (CN)

(21) Appl. No.: 14/092,719

(22) Filed: Nov. 27, 2013

(30) Foreign Application Priority Data
Dec. 17, 2012 (CN) 201210548994.1

(51) Int. Cl. H01L 27/092; H01L 21/8238

(52) U.S. Cl. CPC H01L 27/092; H01L 21/8238
USPC 257/338; 438/199

(57) ABSTRACT

The invention relates to the field of fabricating a semiconductor integrated circuit and particularly to an integrated device and a method for fabricating the integrated device in order to address the problem that a drift area is fabricated on an epitaxial layer but the application scope of the LDMOS is limited due to the costly process of fabricating the epitaxial layer. An integrated device of an nLDMOS and a pLDMOS according to an embodiment of the invention includes a substrate and further includes an nLDMOS and a pLDMOS, where the nLDMOS and the pLDMOS are located in the substrate. The nLDMOS and the pLDMOS is located in the substrate without any epitaxial layer, thereby lowering the fabrication cost and extending the application scope.

This application claims the benefit of China Patent Application No. 201210548994.1, filed on Dec. 17, 2012, which is incorporated herein by reference.

### FIELD OF THE INVENTION

The present invention relates to the field of fabricating a semiconductor integrated circuit and particularly to an integrated device and a method for fabricating the integrated device.

### BACKGROUND OF THE INVENTION

A Complementary Double-diffused Metal Oxide Semiconductor (CDMOS) is an integrated device of a Complementary Metal Oxide Semiconductor (CMOS) and a Double-diffused Metal Oxide Semiconductor (DMOS), where the DMOS can be a Laterally Double-diffused Metal Oxide Semiconductor (LDMOS) and a Vertically Double-diffused Metal Oxide Semiconductor (VDMOS). The LDMOS is easier to be compatible with the CMOS than the VDMOS in process, so the LDMOS is widely used in the integrated circuit design. The device structure of the LDMOS generally includes a body area, a source area, a drain area, a Gate oxide (Gox) layer, a Field oxide (Fox) layer and a poly-silicon (Poly) gate. According to the conductive channel type, the LDMOS is categorized into an N-channel LDMOS (nLDMOS) and a P-channel LDMOS (pLDMOS), where the nLDMOS has a body area which is a lightly doped P-type semiconductor, and a source area and a drain area, both of which are heavily doped N-type semiconductors; and the pLDMOS has a body area which is a lightly doped N-type semiconductor, and a source area and a drain area, both of which are heavily doped P-type semiconductors.

Performance parameters of the LDMOS generally include a breakdown voltage and a conduction resistance, where a higher breakdown voltage and a lower conduction resistance are preferred respectively. In a production application, however, the breakdown voltage and the conduction resistance are two conflicting quantities with each other, that is, the conduction resistance becomes higher or lower as the breakdown voltage is higher or lower. In the prior art, the breakdown voltage of the LDMOS is increased and the conduction resistance of the LDMOS is decreased primarily by fabricating a drift area and a drain protection area, where the drift area of the nLDMOS is fabricated on an N-type epitaxial layer, and the drift area of the pLDMOS is fabricated on a P-type epitaxial layer. An application scope of the LDMOS is limited due to a costly process of fabricating the epitaxial layer.

In summary, the drift area is fabricated on the epitaxial layer to increase the breakdown voltage and decrease the conduction resistance in the existing LDMOS technology, but the application scope of the LDMOS is limited due to the costly process of fabricating the epitaxial layer.

### SUMMARY OF THE INVENTION

Embodiments of the invention provide an integrated device and a method for fabricating the integrated device, a discrete device and a CDMOS, so as to address the problem in the prior art that the drift area is fabricated on the epitaxial layer but the application scope of the LDMOS is limited due to the costly process of fabricating the epitaxial layer.

An embodiment of the invention provides an integrated device which includes a substrate, wherein the integrated device further includes an nLDMOS and a pLDMOS,

wherein the nLDMOS and the pLDMOS are located in the substrate.

An embodiment of the invention provides a discrete device which includes a substrate, a drain N+ doped area and a P-type body area located in the substrate, and a source N+ doped area located in the P-type body area, wherein the discrete device further includes a first N-well and an N-type drift area,

wherein the first N-well is located in the substrate; the N-type drift area, the drain N+ doped area and the P-type body area are located in the first N-well; and the N-type drift area is located between the drain N+ doped area and the P-type body area.

An embodiment of the invention provides a discrete device which includes a substrate, and a drain P+ doped area and a source P+ doped area located in the substrate, wherein the discrete device further includes a second N-well, a P-type drift area and a P-type drain protection area,

wherein the second N-well is located in the substrate; the source P+ doped area, the P-type drift area and the P-type drain protection area are located in the second N-well, and the P-type drift area is located between the source P+ doped area and the P-type drain protection area; and the drain P+ doped area is located in the P-type drain protection area.

An embodiment of the invention provides a Complementary Double-diffused Metal Oxide Semiconductor field effect transistor, CDMOS, including the above-mentioned integrated device.

An embodiment of the invention provides a method for fabricating an integrated device, and the method includes:

forming an nLDMOS and a pLDMOS in a P-type single crystalline substrate.

In an embodiment of the invention, an integrated device includes a substrate and further includes an nLDMOS and a pLDMOS, where the nLDMOS and the pLDMOS are located in the substrate. Since the nLDMOS and the pLDMOS are located in the substrate without any epitaxial layer, the fabrication cost is reduced and the application scope thereof is extended.

### BRIEF DESCRIPTION OF THE DRAWINGS

FIG. 1 is a schematic structural diagram of an integrated device of an nLDMOS and a pLDMOS according to an embodiment of the invention;

FIG. 2 is a schematic structural diagram of an nLDMOS according to an embodiment of the invention;

FIG. 3 is a schematic structural diagram of a pLDMOS according to an embodiment of the invention;

FIG. 4 is a schematic structural diagram of a CDMOS according to an embodiment of the invention;

FIG. 5 is a schematic flow chart of a method for fabricating an integrated device of an nLDMOS and a pLDMOS according to an embodiment of the invention;

FIG. 6A to FIG. 6E are schematic diagrams of a process of fabricating an integrated device of an nLDMOS and a pLDMOS according to an embodiment of the invention;

FIG. 7A to FIG. 7E are schematic diagrams of a process of fabricating an nLDMOS according to an embodiment of the invention;

FIG. 8A to FIG. 8E are schematic diagrams of a process of fabricating a pLDMOS according to an embodiment of the invention; and

FIG. 9A to FIG. 9E are schematic diagrams of a process of fabricating a CDMOS according to an embodiment of the invention.

### DETAILED DESCRIPTION OF THE EMBODIMENTS

In an embodiment of the invention, an integrated device includes a substrate and further includes an nLDMOS and a pLDMOS, where the nLDMOS and the pLDMOS are located in the substrate, that is, the integrated device of the nLDMOS and the pLDMOS described in the embodiment of the invention is fabricated by forming the nLDMOS and the pLDMOS in a P-type single crystalline substrate in non-epitaxial process. The nLDMOS and the pLDMOS are fabricated directly in the substrate without any epitaxial layer in the conventional process to thereby reduce the fabrication cost, increase the performance price ratio, extend the application scope thereof and remedy the drawback in the prior art.

It shall be noted that the integrated device in the embodiment of the invention can be an integrated device of an nLDMOS and a pLDMOS (that is, a device in which an nLDMOS and a pLDMOS are integrated together), and a discrete device in an embodiment of the invention can be a separate device nLDMOS or a separate device pLDMOS.

Embodiments of the invention will be further described below in details with reference to the drawings.

Preferably, in order to reduce the fabrication cost, a device can be fabricated in a substrate in the non-epitaxial process; and in an embodiment of the invention, an nLDMOS and a pLDMOS are fabricated in a substrate, that is, all the components of device structures of the nLDMOS and the pLDMOS are implemented in the substrate without growing any epitaxial layer.

Preferably, the nLDMOS and the pLDMOS in embodiments of the invention can be separate devices (that is, the nLDMOS and the pLDMOS are two separate devices respectively), can be an integrated device of the nLDMOS and the pLDMOS, or the nLDMOS and/or the pLDMOS can be integrated together with other devices, which will be described below respectively.

In a first case, an integrated device of an nLDMOS and a pLDMOS includes a substrate and further includes an nLDMOS and a pLDMOS, where the nLDMOS and the pLDMOS are located in the substrate.

Preferably, the substrate is a P-type single crystalline substrate with a resistivity of 5 to 200 ohms·centimeter.

Preferably, the nLDMOS in the integrated device includes a drain N+ doped area, a P-type body area, and a source N+ doped area located in the P-type body area, and further includes a first N-well and an N-type drift area, where the first N-well is located in the substrate, and the N-type drift area, the drain N+ doped area and the P-type body area are located in the first N-well, and the N-type drift area is located between the drain N+ doped area and the P-type body area.

Here the drain N+ doped area is a drain area formed by N-type heavy doping, and the source N+ doped area is a source area formed by N-type heavy doping.

Preferably, the depth of the first N-well ranges from 2.5 μm to 10 μm and/or the depth of the N-type drift area ranges from 0.4 μm to 2.0 μm.

Preferably, the depth of the P-type body area ranges from 0.6 μm to 1.8 μm.

Preferably, the nLDMOS includes a P+ doped area extending the P-type body area out of the nLDMOS, where the P+ doped area is an area formed by P-type heavy doping.

Preferably, the thickness of a field oxide layer, located on the surface of the substrate, directly above the N-type drift area ranges from 2000 angstroms to 8000 angstroms.

Preferably, the thickness of a gate oxide layer, located on the surface of the substrate uncovered by the field oxide layer, above an active area ranges from 60 angstroms to 1200 angstroms.

Preferably, the thickness of a poly-silicon gate located on partial areas of surfaces of the gate oxide layer and the field oxide layer ranges from 2000 angstroms to 10000 angstroms.

Preferably, the drain N+ doped area is located in the first N-well without any worry about a breakdown occurring at the bottom of the drain N+ doped area, so it is not necessary to set a drain protection area, thereby lowering the cost.

In an implementation, the use of the first N-well and the N-type drift area located in the first N-well can increase the breakdown voltage of the nLDMOS; the use of the poly-silicon gate extending to the surface of the field oxide layer can lower the electric field on the surface and increase the breakdown voltage of the nLDMOS; and both the first N-well and the N-type drift area located in the first N-well participate in current conduction when the nLDMOS is turned on to thereby lower the conduction resistance.

Preferably, the pLDMOS in the integrated device includes a drain P+ doped area and a source P+ doped area, and further includes a second N-well, a P-type drift area and a P-type drain protection area, where the second N-well is located in the substrate; the source P+ doped area, the P-type drift area and the P-type drain protection area are located in the second N-well, and the P-type drift area is located between the source P+ doped area and the P-type drain protection area; and the drain P+ doped area is located in the P-type drain protection area.

Here the drain P+ doped area is a drain area formed by P-type heavy doping, and the source P+ doped area is a source area formed by P-type heavy doping.

Preferably, the depth of the second N-well ranges from 2.5 μm to 10 μm; and/or

The depth of the P-type drift area ranges from 0.4 μm to 2.0 μm; and/or

The depth of the P-type drain protection area ranges from 0.6 μm to 1.8 μm.

Preferably, the second N-well is an N-type body area of the pLDMOS, and the pLDMOS includes an N+ doped area extending the N-type body area out of the pLDMOS, where the N+ doped area is an area formed by N-type heavy doping.

Preferably, the thickness of a field oxide layer, located on the surface of the substrate, above the P-type drift area ranges from 2000 angstroms to 8000 angstroms.

Preferably, the thickness of a gate oxide layer, located on the surface of the substrate uncovered by the field oxide layer, above an active area ranges from 60 angstroms to 1200 angstroms.

Preferably, the thickness of a poly-silicon gate located on partial areas of surfaces of the gate oxide layer and the field oxide layer ranges from 2000 angstroms to 10000 angstroms.

Preferably, a P-field doped area is used as the P-type drift area to thereby increase the breakdown voltage of the pLDMOS, where the P-field doped area is an area formed by P-field doping in the CMOS fabrication process.

In an implementation, the use of the poly-silicon gate extending to the surface of the field oxide layer can lower the electric field on the surface and increase the breakdown voltage of the pLDMOS, and the presence of the P-type drain protection area can lower the conduction resistance.

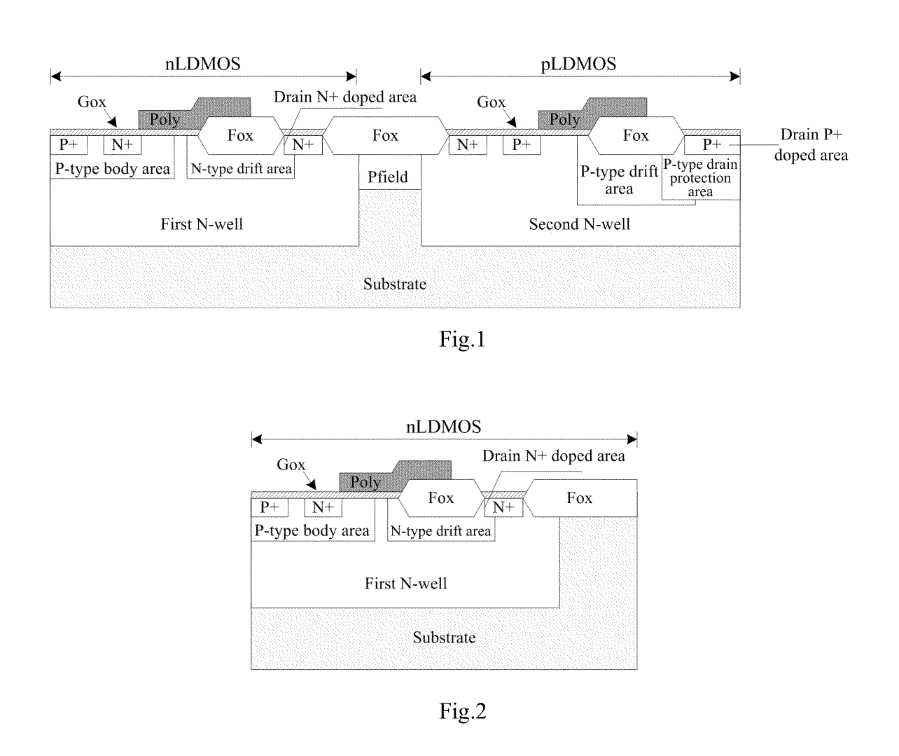

FIG. 1 illustrates a schematic structural diagram of the integrated device of the nLDMOS and the pLDMOS according to the embodiment of the invention, where Gox represents the gate oxide layer, Fox represents the field oxide layer, and Poly represents the poly-silicon gate layer.

In the embodiment of the invention, the drain N+ doped area, the N-type drift area and the P-type body area of the nLDMOS in the integrated device of the nLDMOS and the pLDMOS are located in the first N-well, where the N-type drift area is located between the drain N+ doped area and the P-type body area of the nLDMOS; and the source N+ doped area of the nLDMOS is located in the P-type body area, and the P+ doped area is used to extend the P-type body area out of the nLDMOS.

In the embodiment of the invention, the source P+ doped area, the P-type drift area and the P-type drain protection area of the pLDMOS in the integrated device of the nLDMOS and the pLDMOS are located in the second N-well, where the P-type drift area is located between the source P+ doped area and the P-type drain protection area of the pLDMOS; and the drain P+ doped area of the pLDMOS is located in the P-type drain protection area, and the N+ doped area is used to extend the N-type body area (the second N-well) out of the pLDMOS.

Here the field oxide layer isolates the nLDMOS from the pLDMOS, and the P-field doped area, isolating the nLDMOS from the pLDMOS, below the field oxide layer is the same as the P-field doped area described above.

In a second case, there is a discrete device nLDMOS.

In an implementation, the discrete device nLDMOS is structurally similar to the nLDMOS in the integrated device of the nLDMOS and the pLDMOS described in the first case.

Preferably, a discrete device nLDMOS according to an embodiment of the invention includes a substrate, a drain N+ doped area and a P-type body area located in the substrate, and a source N+ doped area located in the P-type body area, and further includes a first N-well and an N-type drift area, where the first N-well is located in the substrate; the N-type drift area, the drain N+ doped area and the P-type body area are located in the first N-well; and the N-type drift area is located between the drain N+ doped area and the P-type body area.

Preferably, the substrate is a P-type single crystalline substrate with a resistivity of 5 to 200 ohms·centimeter.

Preferably, the depth of the first N-well ranges from 2.5 μm to 10 μm and/or the depth of the N-type drift area ranges from 0.4 μm to 2.0 μm.

Preferably, the depth of the P-type body area ranges from 0.6 μm to 1.8 μm.

Preferably, the nLDMOS includes a P+ doped area extending the P-type body area out of the nLDMOS.

Preferably, the thickness of a field oxide layer, located on the surface of the substrate, directly above the N-type drift area ranges from 2000 angstroms to 8000 angstroms.

Preferably, the thickness of a gate oxide layer, located on the surface of the substrate uncovered by the field oxide layer, above an active area ranges from 60 angstroms to 1200 angstroms.

Preferably, the thickness of a poly-silicon gate located on partial areas of surfaces of the gate oxide layer and the field oxide layer ranges from 2000 angstroms to 10000 angstroms.

Preferably, the drain N+ doped area is located in the first N-well without any worry about a breakdown occurring at the bottom of the drain N+ doped area, so it is not necessary to set a drain protection area, thereby lowering the cost.

In an implementation, the use of the first N-well and the N-type drift area located in the first N-well can increase the breakdown voltage of the nLDMOS; the use of the poly-silicon gate extending to the surface of the field oxide layer can lower the electric field on the surface and increase the breakdown voltage of the nLDMOS; and both the first N-well and the N-type drift area located in the first N-well participate in current conduction when the nLDMOS is turned on to thereby lower the conduction resistance.

FIG. 2 illustrates a schematic structural diagram of the discrete device nLDMOS according to the embodiment of the invention, where Gox represents the gate oxide layer, Fox represents the field oxide layer, and Poly represents the poly-silicon gate layer.

The P+ doped area extending the P-type body area out of the nLDMOS and the source N+ doped area are located in the P-type body area; the P-type body area, the N-type drift area and the drain N+ doped area are located in the first N-well, where the N-type drift area is located between the drain N+ doped area and the P-type body area; and the first N-well is located in the P-type substrate.

In a third case, there is a discrete device pLDMOS.

In an implementation, the discrete device pLDMOS is structurally similar to the pLDMOS in the integrated device of the nLDMOS and the pLDMOS described in the first case.

Preferably, a pLDMOS according to an embodiment of the invention includes a substrate, and a drain P+ doped area and a source P+ doped area located in the substrate, and further includes a second N-well, a P-type drift area and a P-type drain protection area, where the second N-well is located in the substrate; the source P+ doped area, the P-type drift area and the P-type drain protection area are located in the second N-well, where the P-type drift area is located between the source P+ doped area and the P-type drain protection area; and the drain P+ doped area is located in the P-type drain protection area.

Preferably, the depth of the second N-well ranges from 2.5 μm to 10 μm; and/or

The depth of the P-type drift area ranges from 0.4 μm to 2.0 μm; and/or

The depth of the P-type drain protection area ranges from 0.6 μm to 1.8 μm.

Preferably, the second N-well is an N-type body area of the pLDMOS, and the pLDMOS includes an N+ doped area extending the N-type body area out of the pLDMOS.

Preferably, the thickness of a field oxide layer, located on the surface of the substrate, above the P-type drift area ranges from 2000 angstroms to 8000 angstroms.

Preferably, the thickness of a gate oxide layer, located on the surface of the substrate uncovered by the field oxide layer, above an active area ranges from 60 angstroms to 1200 angstroms.

Preferably, the thickness of a poly-silicon gate located on partial areas of surfaces of the gate oxide layer and the field oxide layer ranges from 2000 angstroms to 10000 angstroms.

Preferably, a P-field doped area is used as the P-type drift area to thereby increase the breakdown voltage of the pLDMOS, where the P-field doped area is an area formed by P-field doping in the CMOS fabrication process.

In an implementation, the use of the poly-silicon gate extending to the surface of the field oxide layer can lower the electric field on the surface and increase the breakdown voltage of the pLDMOS, and the presence of the P-type drain protection area can lower the conduction resistance.

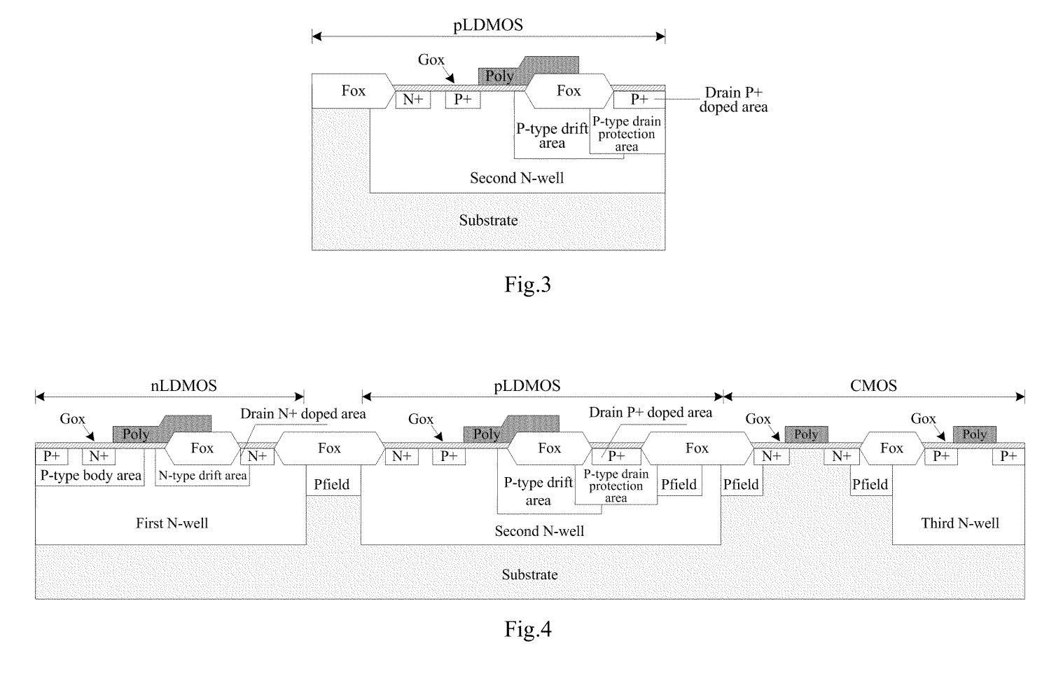

FIG. 3 illustrates a schematic structural diagram of the discrete device pLDMOS according to the embodiment of the invention, where Gox represents the gate oxide layer, Fox represents the field oxide layer, and Poly represents the poly-silicon gate layer.

The drain P+ doped area is located in the P-type drain protection area; the P-type drain protection area, the P-type drift area, the source P+ doped area, and the N+ doped area extending the N-type body area out of the pLDMOS are located in the second N-well, where the P-type drift area is located between the source P+ doped area and the P-type drain protection area; and the second well is located in the P-type substrate.

In a fourth case, the integrated device of the nLDMOS and the pLDMOS according to the embodiment of the invention is integrated together with a CMOS to constitute a CDMOS, where the CDMOS refers to a device including a CMOS and a DMOS.

Particularly the CMOS in the CDMOS can be any CMOS device.

In an implementation, the integrated device of the nLDMOS and the pLDMOS without any epitaxial layer can be easily integrated with the CMOS device in the same chip.

In an implementation, the integration of the integrated device of the nLDMOS and the pLDMOS with the CMOS (i.e., the CDMOS) according to the embodiment of the invention can perform Direct Current-Direct Current (DC-DC) conversion, Alternating Current-Direct Current (AC-DC) conversion and full-bridge driving.

FIG. 4 illustrates a schematic structural diagram of the CDMOS according to the embodiment of the invention, where Gox represents the gate oxide layer, Fox represents the field oxide layer, and Poly represents the poly-silicon gate layer.

The nLDMOS and the pLDMOS in FIG. 4 are structurally identical to the nLDMOS and the pLDMOS in the integrated device of the nLDMOS and the pLDMOS.

The CMOS structure in FIG. 4 is a conventional CMOS structure, where the source N+ doped area, the drain N+ doped area, and the gate extended by the Poly located on the surface of the gate oxide layer on the surfaces of the source N+ doped area and the drain N+ doped area constitute an NMOS; the source P+ doped area and the drain P+ doped area located in a third N-well, and the gate extended by the Poly located on the surface of the gate oxide layer on the surfaces of the source P+ doped area and the drain P+ doped area constitute a PMOS; and the NMOS is isolated from the PMOS by the field oxide layer.

It shall be noted that the embodiments of the invention will not be limited to the integration case described in the fourth case, but an nLDMOS and/or a pLDMOS can also be integrated with another device without departing from the scope of the invention, and an implementation in which an nLDMOS and/or a pLDMOS is integrated with another device is similar to the implementation in the fourth case according to the embodiment of the invention, and a repeated description thereof will be omitted here.

Preferably, embodiments of the invention further provide methods for fabricating the respective integrated devices and discrete devices described above, which will be described below respectively, and it shall be noted that a P-field (a P-field doped area), located in a substrate, below a field oxide layer will not be described in the embodiments of the invention so as to highlight the focus of the invention.

In a first case, there is a method for fabricating an integrated device of an nLDMOS and a pLDMOS according to an embodiment of the invention.

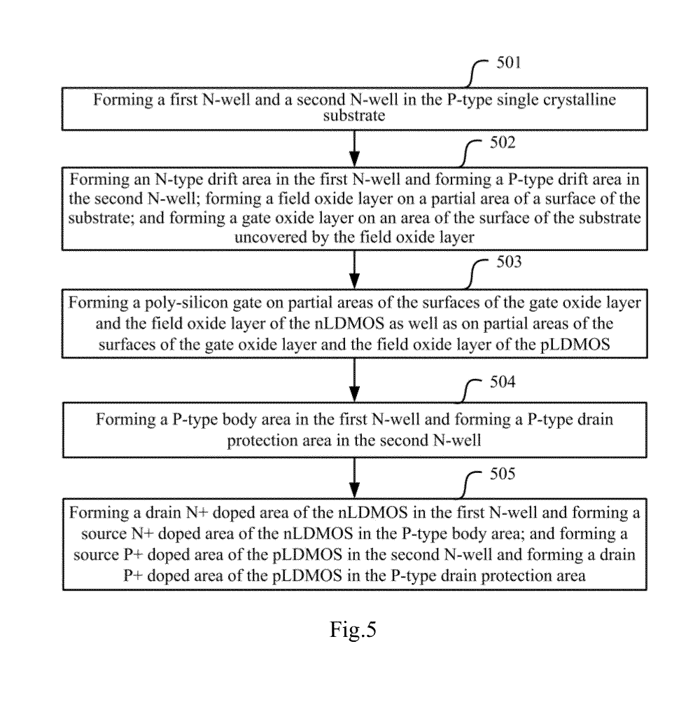

As illustrated in FIG. 5, a method for fabricating an integrated device of an nLDMOS and a pLDMOS according to an embodiment of the invention includes:

The nLDMOS and the pLDMOS are formed in a P-type single crystalline substrate.

Preferably, the nLDMOS and the pLDMOS are formed in the P-type single crystalline substrate as follows:

Step 501, forming a first N-well and a second N-well in the P-type single crystalline substrate.

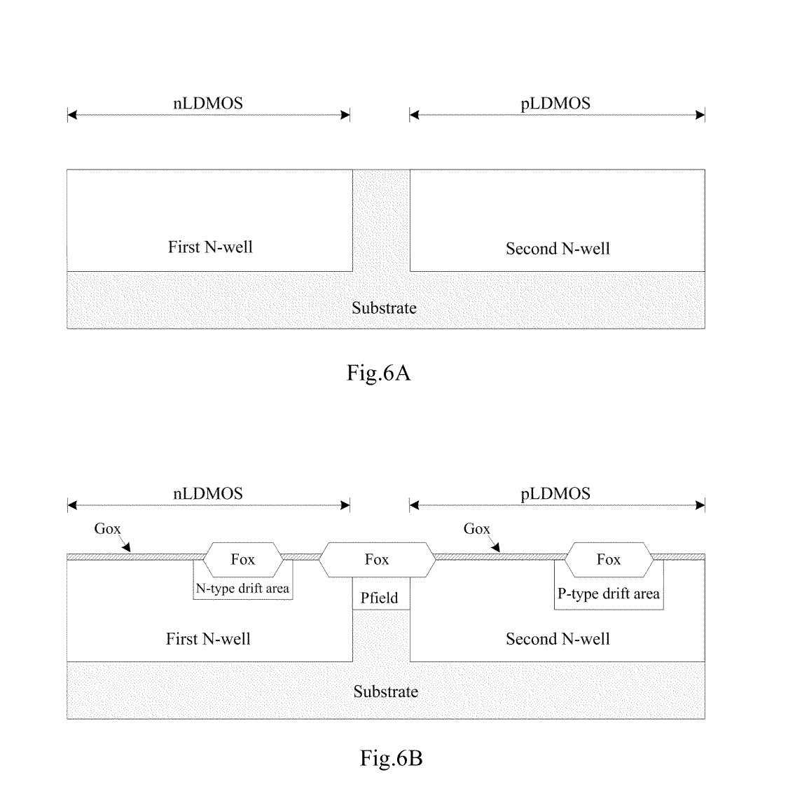

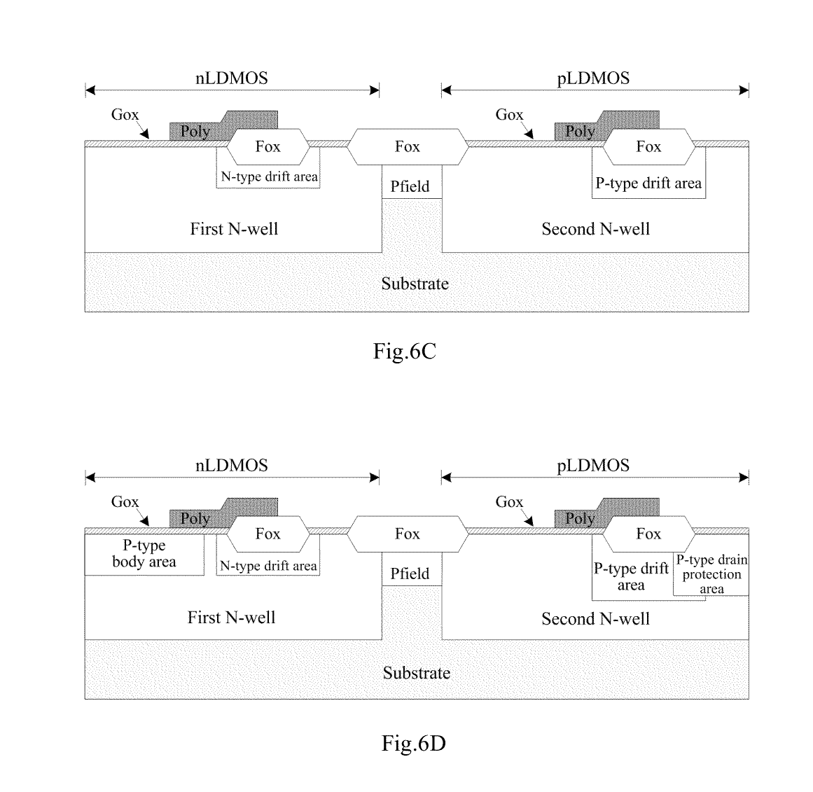

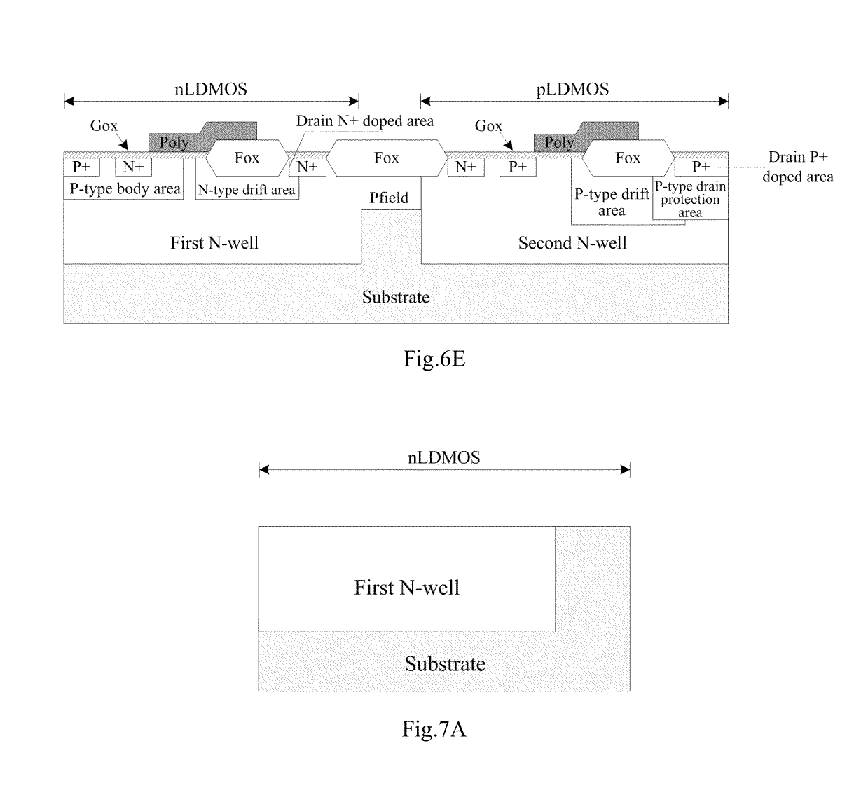

In an implementation, the first N-well and the second N-well are formed in the P-type single crystalline substrate in photo-lithography, ion injection, diffusion and other process steps, particularly as illustrated in FIG. 6A.

Preferably, the dosage of injected ions ranges from 2E12 atoms/cm² to 8E12 atoms/cm², and the injected ions are elements of family V.

Step 502, forming an N-type drift area in the first N-well and forming a P-type drift area in the second N-well; forming a field oxide layer on a partial area of a surface of the substrate; and forming a gate oxide layer on an area of the surface of the substrate uncovered by the field oxide layer.

In an implementation, the N-type drift area is formed in the first N-well and the P-type drift area is formed in the second N-well, the field oxide layer is formed on the partial area of the surface of the substrate, and the gate oxide layer is formed on the area of the surface of the substrate uncovered by the field oxide layer in photo-lithography, ion injection, diffusion, oxidation and other process steps, particularly as illustrated in FIG. 6B.

Preferably, the dosage of ions injected to form the N-type drift area ranges from 1E12 atoms/cm² to 1E13 atoms/cm², and the injected ions are elements of family V.

Preferably, the P-type drift area is formed in the second N-well as follows:

The P-type drift area is formed in the second N-well by P-field doping, that is, a P-field doped area is used as the P-type drift area.

Preferably, the dosage of ions injected to form the P-type drift area ranges from 3E12 atoms/cm² to 1E14 atoms/cm², and the injected ions are elements of family III.

Step 503, forming a poly-silicon gate on partial areas of the surfaces of the gate oxide layer and the field oxide layer of the nLDMOS as well as on partial areas of the surfaces of the gate oxide layer and the field oxide layer of the pLDMOS.

In an implementation, the poly-silicon gate is formed on the partial areas of the surfaces of the gate oxide layer and the field oxide layer of the nLDMOS as well as on the partial areas of the surfaces of the gate oxide layer and the field oxide layer of the pLDMOS in deposition, photo-lithography, etching and other process steps, particularly as illustrated in FIG. 6C.

Step 504, forming a P-type body area in the first N-well and forming a P-type drain protection area in the second N-well.

In an implementation, the P-type body area is formed in the first N-well and the P-type drain protection area is formed in the second N-well in photo-lithography, ion injection, diffusion and other process steps, particularly as illustrated in FIG. 6D.

Preferably, the P-type body area is formed in the first N-well and the P-type drain protection area is formed in the second N-well as follows:

The P-type body area is formed in the first N-well and the P-type drain protection area is formed in the second N-well in the same process, that is, the same process steps, process materials, process principle, etc., are adopted. Thus the P-type body area formed in the first N-well is the same as the P-type drain protection area formed in the second N-well (the P-type drain protection area can be regarded as a P-type body area).

In an implementation, the P-type body area and the P-type drain protection area are formed concurrently in the same process to thereby lower the process cost.

Preferably, the dosage of ions injected to form the P-type body area ranges from 4E12 atoms/cm² to 5E13 atoms/cm², and the injected ions are elements of family III.

Preferably, the dosage of ions injected to form the P-type drain protection area ranges from 4E12 atoms/cm² to 5E13 atoms/cm², and the injected ions are elements of family III.

Step 505, forming a drain N+ doped area of the nLDMOS in the first N-well and forming a source N+ doped area of the nLDMOS in the P-type body area; and forming a source P+ doped area of the pLDMOS in the second N-well and forming a drain P+ doped area of the pLDMOS in the P-type drain protection area.

In an implementation, the drain N+ doped area of the nLDMOS is formed in the first N-well, and the source N+ doped area of the nLDMOS is formed in the P-type body area; and the source P+ doped area of the pLDMOS is formed in the second N-well, and the drain P+ doped area of the pLDMOS is formed in the P-type drain protection area in photo-lithography, ion injection, annealing and other process steps, particularly as illustrated in FIG. 6E.

As illustrated in FIG. 6E, a P+ doped area extending the P-type body area out and an N+ doped area extending the N-type body area are further formed.

Preferably, the dosage of ions injected to form the N+ doped area ranges from 1E15 atoms/cm² to 1E16 atoms/cm², and the injected ions are elements of family V.

Preferably, the dosage of ions injected to form the P+ doped area ranges from 1E15 atoms/cm² to 1E16 atoms/cm², and the injected ions are elements of family III.

In an implementation, wire-leading hole, metal wiring, passivation layer processing and other subsequent process steps are the same as those in the existing conventional process, and a repeated description thereof will be omitted here.

In a second case, there is a method for fabricating a discrete device nLDMOS according to an embodiment of the invention.

In an implementation, a flow of the method for fabricating a discrete device nLDMOS is similar to the flow of the method for fabricating the nLDMOS in the integrated device of the nLDMOS and the pLDMOS, and reference can be made to the implementation of the method for fabricating the nLDMOS in the integrated device of the nLDMOS and the pLDMOS for an implementation of the method for fabricating a discrete device nLDMOS.

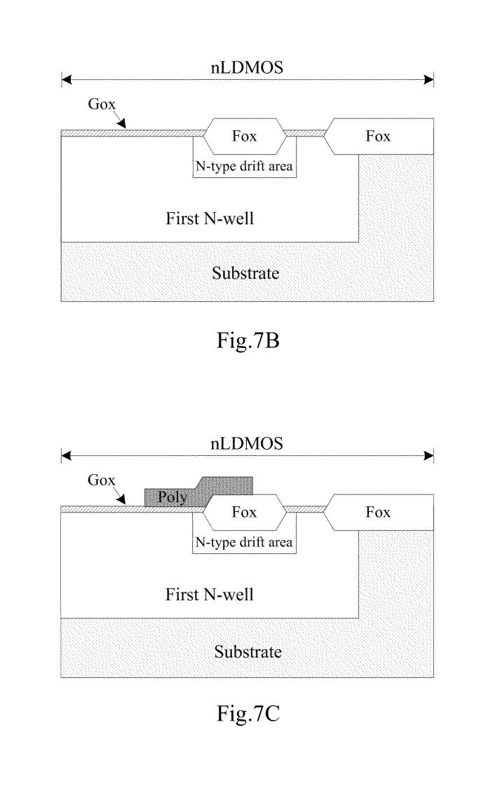

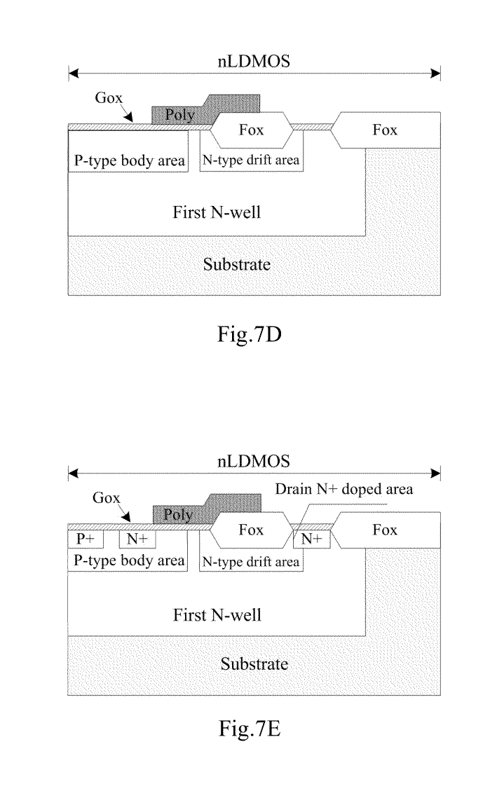

FIG. 7A to FIG. 7E are schematic diagrams of the process of fabricating an nLDMOS according to an embodiment of the invention, and as illustrated in FIG. 7A, a first N-well is formed in a P-type substrate;

As illustrated in FIG. 7B, an N-type drift area is formed in the first N-well, a field oxide layer is formed on a partial area of the surface of the substrate, and a gate oxide layer is formed on an area of the surface of the substrate uncovered by the field oxide layer;

As illustrated in FIG. 7C, a poly-silicon gate is formed on partial areas of surfaces of the gate oxide layer and the field oxide layer;

As illustrated in FIG. 7D, a P-type body area is formed in the first N-well; and

As illustrated in FIG. 7E, a drain N+ doped area of the nLDMOS is formed in the first N-well, a P+ doped area extending the P-type body area out is formed in the first N-well, and a source N+ doped area of the nLDMOS is formed in the P-type body area.

In a third case, there is a method for fabricating a discrete device pLDMOS according to an embodiment of the invention.

In an implementation, a flow of the method for fabricating a discrete device pLDMOS is similar to the flow of the method for fabricating the pLDMOS in the integrated device of the nLDMOS and the pLDMOS, and reference can be made to the implementation of the method for fabricating the pLDMOS in the integrated device of the nLDMOS and the pLDMOS for an implementation of the method for fabricating a discrete device pLDMOS.

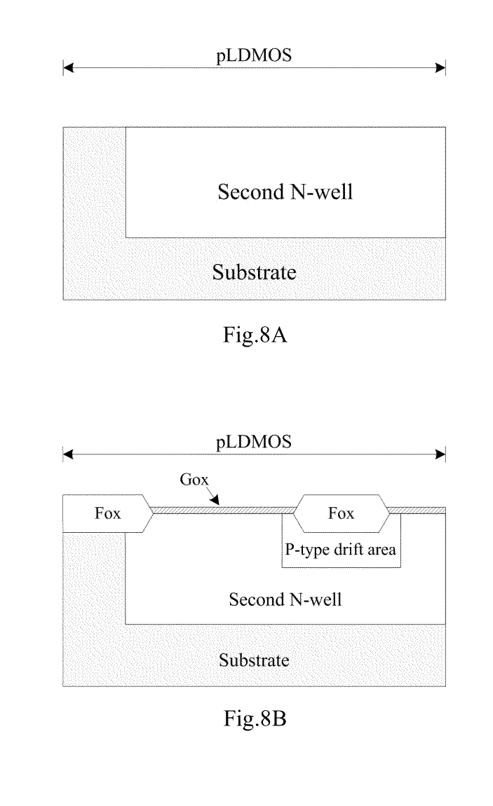

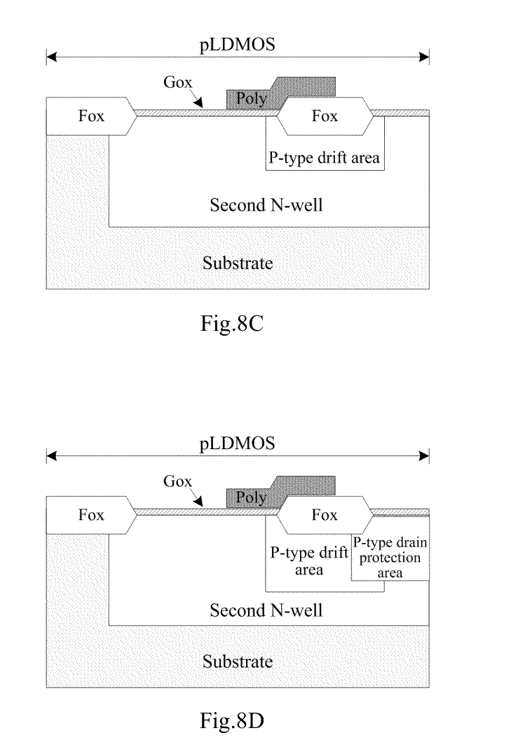

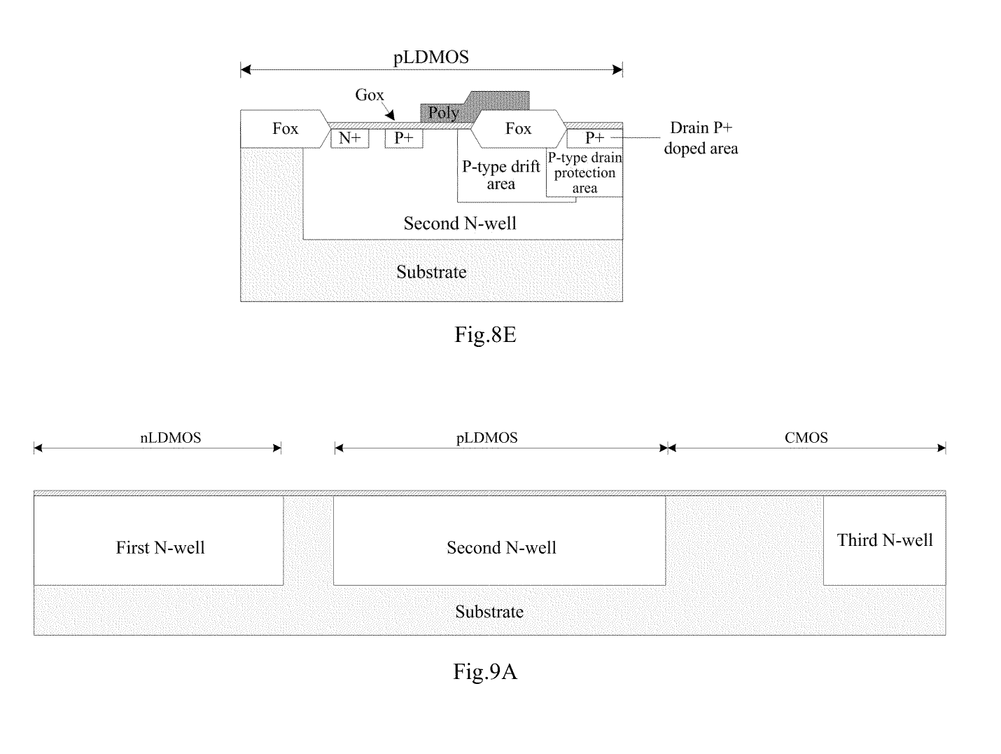

FIG. 8A to FIG. 8E are schematic diagrams of the process of fabricating a pLDMOS according to an embodiment of the invention, and as illustrated in FIG. 8A, a second N-well is formed in a P-type substrate;

As illustrated in FIG. 8B, a P-type drift area is formed in the second N-well, a field oxide layer is formed on a partial area of the surface of the substrate, and a gate oxide layer is formed on an area of the surface of the substrate uncovered by the field oxide layer;

As illustrated in FIG. 8C, a poly-silicon gate is formed on partial areas of surfaces of the gate oxide layer and the field oxide layer;

As illustrated in FIG. 8D, a P-type drain protection area is formed in the second N-well; and

As illustrated in FIG. 8E, a source P+ doped area of the pLDMOS is formed in the second N-well, an N+ doped area extending the N-type body area out is formed in the second N-well, and a drain P+ doped area of the pLDMOS is formed in the P-type drain protection area.

In a fourth case, there is a method for fabricating a CDMOS constituted by integrating an integrated device of an nLDMOS and a pLDMOS together with a CMOS according to an embodiment of the invention.

In an implementation, a flow of the method for fabricating a CDMOS is similar to the flow of the method for fabricating the integrated device of the nLDMOS and the pLDMOS except that a CMOS is fabricated together with the nLDMOS and the pLDMOS, and reference can be made to the implementation of the method for fabricating the integrated device of the nLDMOS and the pLDMOS for an implementation of the method for fabricating a CDMOS.

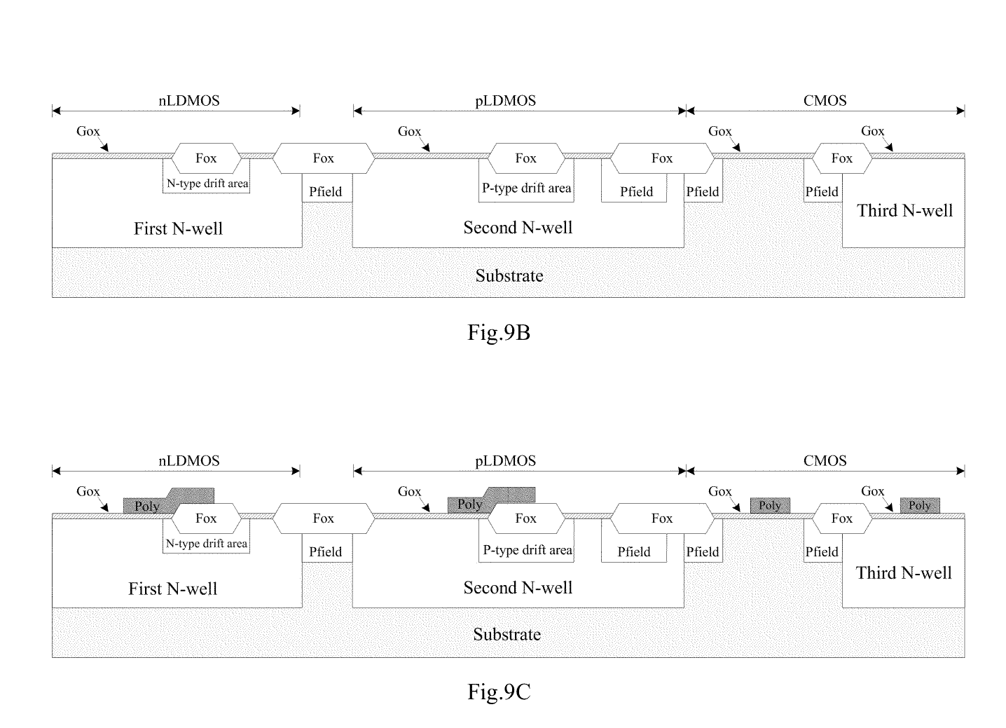

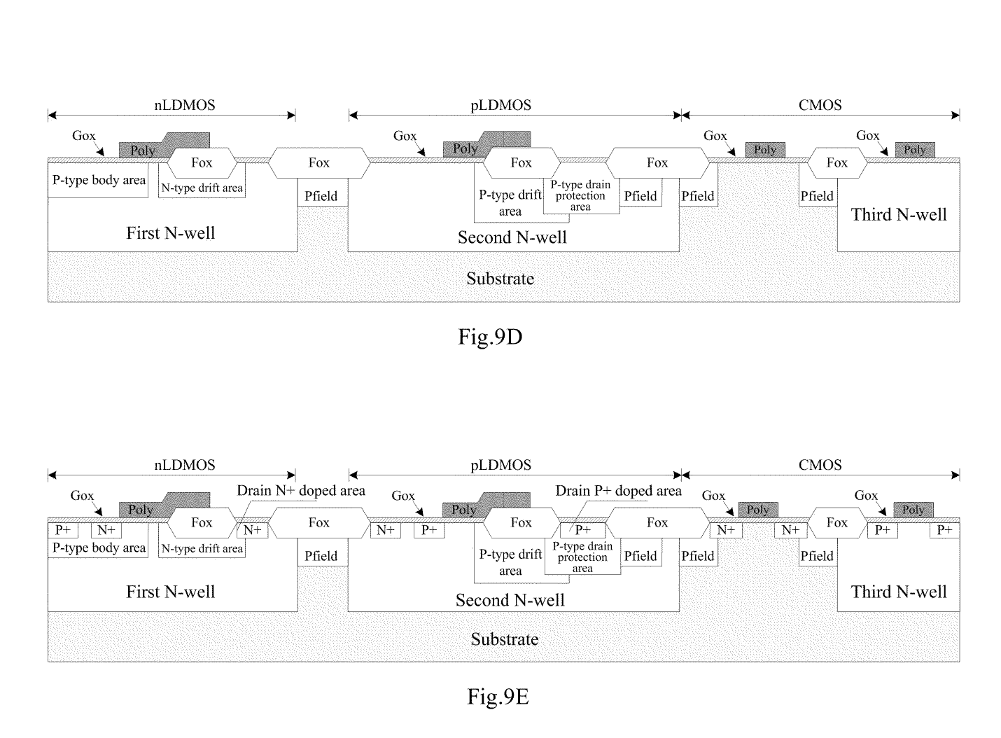

FIG. 9A to FIG. 9E are schematic diagrams of the process of fabricating a CDMOS according to an embodiment of the invention, and as illustrated in FIG. 9A, a first N-well, a second N-well and a third N-well are formed in a P-type substrate;

As illustrated in FIG. 9B, an N-type drift area is formed in the first N-well, a P-type drift area is formed in the second N-well, a field oxide layer is formed on a partial area of the surface of the substrate, and a gate oxide layer is formed on an area of the surface of the substrate uncovered by the field oxide layer;

As illustrated in FIG. 9C, a poly-silicon gate is formed on partial areas of the surfaces of the gate oxide layer and the field oxide layer;

As illustrated in FIG. 9D, a P-type body area is formed in the first N-well, and a P-type drain protection area is formed in the second N-well; and

As illustrated in FIG. 9E, a drain N+ doped area of the nLDMOS is formed in the first N-well, a P+ doped area extending the P-type body area out is formed in the first N-well, and a source N+ doped area of the nLDMOS is formed in the P-type body area; a source P+ doped area of the pLDMOS is formed in the second N-well, an N+ doped area extending the N-type body area out is formed in the second N-well, and a drain P+ doped area of the pLDMOS is formed in the P-type drain protection area; and a source N+ doped area and a drain N+ doped area of an NMOS are formed in the P-type substrate, and a source P+ doped area and a drain P+ doped area of a PMOS is formed in the third N-well.

It shall be noted that an implementation of a method for fabricating an integrated device of an nLDMOS and/or a pLDMOS with another device according to an embodiment of the invention is similar to the implementation of the method for fabricating a discrete device nLDMOS and/or pLDMOS according to the embodiment of the invention, and a repeated description thereof will be omitted here.

Although the preferred embodiments of the invention have been described, those skilled in the art benefiting from the underlying inventive concept can make additional modifications and variations to these embodiments. Therefore the appended claims are intended to be construed as encompassing the preferred embodiments and all the modifications and variations coming into the scope of the invention.

Evidently those skilled in the art can make various modifications and variations to the invention without departing from the spirit and scope of the invention. Thus the invention is also intended to encompass these modifications and variations thereto so long as these modifications and variations come into the scope of the claims appended to the invention and their equivalents.

1. An integrated device, comprising a substrate, wherein the integrated device further comprises an N-channel Laterally Double-diffused Metal Oxide Semiconductor field effect transistor, nLDMOS, and a P-channel Laterally Double-diffused Metal Oxide Semiconductor field effect transistor, pLDMOS,
wherein the nLDMOS and the pLDMOS are located in the substrate.

2. The integrated device according to claim 1, wherein the substrate is a P-type single crystalline substrate with a resistivity of 5 to 200 ohms·centimeter.

3. The integrated device according to claim 1, wherein a drain N+ doped area, an N-type drift area and a P-type body area of the nLDMOS are located in a first N-well, and the N-type drift area is located between the drain N+ doped area and the P-type body area of the nLDMOS; and a source N+ doped area of the nLDMOS is located in the P-type body area.

4. The integrated device according to claim 3, wherein a depth of the first N-well ranges from 2.5 μm to 10 μm and/or a depth of the N-type drift area ranges from 0.4 μm to 2.0 μm.

5. The integrated device according to claim 1, wherein a source P+ doped area, a P-type drift area and a P-type drain protection area of the pLDMOS are located in a second N-well, and the P-type drift area is located between the source P+ doped area and the P-type drain protection area of the pLDMOS; and a drain P+ doped area of the pLDMOS is located in the P-type drain protection area.

6. The integrated device according to claim 5, wherein the second N-well is an N-type body area of the pLDMOS.

7. The integrated device according to claim 5, wherein a depth of the second N-well ranges from 2.5 μm to 10 μm; and/or
a depth of the P-type drift area ranges from 0.4 μm to 2.0 μm; and/or
a depth of the P-type drain protection area ranges from 0.6 μm to 1.8 μm.

8. A method for fabricating the integrated device according to claim 1, the method comprising:
forming an N-channel Laterally Double-diffused Metal Oxide Semiconductor field effect transistor, nLDMOS, and a P-channel Laterally Double-diffused Metal Oxide Semiconductor field effect transistor, pLDMOS, in a P-type single crystalline substrate.

9. The method according to claim 8, wherein forming the nLDMOS and the pLDMOS in the P-type single crystalline substrate comprises:
forming a first N-well and a second N-well in the P-type single crystalline substrate;
forming an N-type drift area in the first N-well and forming a P-type drift area in the second N-well, forming a field oxide layer on a partial area of a surface of the substrate, and forming a gate oxide layer on an area of the surface of the substrate uncovered by the field oxide layer;
forming a poly-silicon gate on partial areas of surfaces of the gate oxide layer and the field oxide layer of the nLDMOS as well as on partial areas of surfaces of the gate oxide layer and the field oxide layer of the pLDMOS;
forming a P-type body area in the first N-well and forming a P-type drain protection area in the second N-well; and
forming a drain N+ doped area of the nLDMOS in the first N-well, forming a source N+ doped area of the nLDMOS in the P-type body area, forming a source P+ doped area of the pLDMOS in the second N-well, and forming a drain P+ doped area of the pLDMOS in the P-type drain protection area.

10. The method according to claim 9, wherein forming the P-type drift area in the second N-well comprises:
forming the P-type drift area in the second N-well through P-field doping.

11. The method according to claim 9, wherein forming the P-type body area in the first N-well and forming the P-type drain protection area in the second N-well comprises:
forming the P-type body area in the first N-well and forming the P-type drain protection area in the second N-well in same process.
